(19) United States
(12) Patent Application Publication
(10) Pub. No.: US 2026/0129920 A1
(43) Pub. Date: May 7, 2026

(54) SEMICONDUCTOR DEVICE AND METHOD OF MANUFACTURING THE SAME

(71) Applicant: Magnachip Semiconductor, Ltd., Cheongju-si (KR)

(72) Inventors: Young Seo JO, Goyang-si (KR); Ji Yong LIM, Seoul (KR); Ki Hwan KIM, Seoul (KR)

(73) Assignee: Magnachip Semiconductor, Ltd., Cheongju-si (KR)

(21) Appl. No.: 19/332,357

(22) Filed: Sep. 18, 2025

(30) Foreign Application Priority Data
Nov. 1, 2024 (KR) 10-2024-0153615

(51) Int. Cl. H10D 62/10; H10D 12/00; H10D 12/01; H10D 30/01; H10D 30/66; H10D 64/00

(52) U.S. Cl. CPC H10D 62/107; H10D 12/032; H10D 12/415; H10D 30/0291; H10D 30/665; H10D 64/111

(57) ABSTRACT

A semiconductor device includes an active area and a junction termination area, each including a drain electrode, a first epitaxial layer of a first conductivity type disposed on the drain electrode, and a second epitaxial layer of the first conductivity type disposed on the first epitaxial layer. The junction termination area further includes a first junction termination area etched on a portion of the second epitaxial layer, and a second junction termination area that is not etched. A field oxide layer is disposed on a portion of the first junction termination area. A doped region of a second conductivity type is disposed to extend from beneath the field oxide layer to the second junction termination area.

### CROSS-REFERENCE TO RELATED APPLICATION

This application claims the benefit under 35 U.S.C. § 119(a) of Korean Patent Application No. 10-2024-0153615, filed on Nov. 1, 2024, the entire disclosure of which is incorporated herein by reference for all purposes.

### BACKGROUND

### 1. Field

The present disclosure relates to a semiconductor device capable of achieving a more stable withstand voltage compared to the conventional art, and a method for manufacturing the same.

### 2. Description of Background

Power semiconductor devices, such as MOSFETS (Metal-Oxide Semiconductor Field Effect Transistors) and IGBTs (Insulated Gate Bipolar Transistors), are primarily used as semiconductor switching devices in power electronics applications. Among these power semiconductor devices, IGBTs can be classified into a horizontal structure, in which a source (or emitter), a gate (or base), and a drain (or collector) electrode are all formed on the upper surface of a semiconductor substrate, and a vertical structure, in which the source and gate electrodes are formed on a top surface of the semiconductor substrate and the drain electrode is formed on a bottom surface of the semiconductor substrate.

For IGBT devices, it may be desirable to reduce electric field peaks that occur at the substrate surface in a termination area. The maximum electric field peak typically occurs within a junction termination area where an equipotential ring is present. Under extremely high-current and high-voltage conditions, this region becomes significantly weakened, resulting in avalanche breakdown due to a large leakage current density under reverse bias. To prevent this, techniques such as adopting a P-ring structure by forming a plurality of P-type conductive rings or increasing the area of the junction termination area to reduce the electric field have been proposed.

While the P-ring structure can reduce the electric field to a certain extent, it exhibits limitations when applied to high-voltage devices. Alternatively, increasing the junction termination area can further reduce the electric field, but this approach leads to an undesirable increase in device size, thereby presenting another issue.

Such IGBT semiconductor devices must be capable of dispersing the electric field generated under reverse bias conditions, thereby reducing the electric field peak and securing a stable breakdown voltage, which is associated with the withstand voltage of the semiconductor device.

Therefore, various approaches have been proposed to improve the structure of semiconductor devices in order to enhance withstand voltage performance.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes an active area and a junction termination area, each including a drain electrode, a first epitaxial layer of a first conductivity type disposed on the drain electrode, and a second epitaxial layer of the first conductivity type disposed on the first epitaxial layer. The junction termination area further includes a first junction termination area etched on a portion of the second epitaxial layer, and a second junction termination area that is not etched. A field oxide layer is disposed on a portion of the first junction termination area. A doped region of a second conductivity type is disposed to extend from beneath the field oxide layer to the second junction termination area.

The doped region may include a lightly doped region of the second conductivity type disposed in the first junction termination area, and a heavily doped region of the second conductivity type disposed to extend from the first junction termination area to the second junction termination area.

A thickness of the heavily doped region may be greater than a thickness of the lightly doped region.

A surface of the field oxide layer may be coplanar with a surface of the second epitaxial layer present in the second junction termination area.

The semiconductor device may further include a body region of the second conductivity type formed between trench gates in the active area, wherein the body region is connected to the doped region.

The semiconductor device may further include a layer of a second conductivity type formed between the drain electrode and the first epitaxial layer.

The junction termination area may further include a junction termination etching region disposed between the field oxide layer and the second junction termination area; a field plate insulating layer disposed on inner and outer upper surfaces of the junction termination etching region; a field plate disposed on the field plate insulating layer; an interlayer insulating layer disposed on the field plate; and a source electrode and a gate electrode formed on the interlayer insulating layer.

In another general aspect, a semiconductor device includes an active area and a junction termination area, each including: a drain electrode; a first epitaxial layer of a first conductivity type disposed on the drain electrode; and a second epitaxial layer of the first conductivity type disposed on the first epitaxial layer. The junction termination area further includes a first junction termination area etched on a portion of the second epitaxial layer, and a second junction termination area that is not etched. A field oxide layer is disposed on a portion of the first junction termination area. Doping regions of a second conductivity type with different thicknesses are disposed in the first junction termination area and the second junction termination area.

The semiconductor device may further include a body region of the second conductivity type formed between trench gates in the active area, wherein the body region is connected to the doped region.

The doped regions may include a lightly doped region of the second conductivity type disposed on the first junction termination area, and a heavily doped region of the second conductivity type disposed to extend from the first junction termination area to the second junction termination area and having a higher doping concentration than the lightly doped region of the second conductivity type.

A thickness of the heavily doped region may be greater than a thickness of the lightly doped region.

A doping concentration of the lightly doped region may gradually decrease toward an edge of the first junction termination area.

The semiconductor device may further include a source electrode electrically contacting the heavily doped region; a field plate disposed on a portion of the heavily doped region and on the lightly doped region; and a gate electrode electrically contacting the field plate.

The semiconductor device may further include a layer of a second conductivity type formed between the drain electrode and the first epitaxial layer.

In another general aspect, a method of manufacturing a semiconductor device including an active area and a junction termination area includes forming a first epitaxial layer of a first conductivity type on a semiconductor substrate of the first conductivity type; forming a second epitaxial layer of the first conductivity type on the first epitaxial layer; etching an upper surface portion of the second epitaxial layer located in the junction termination area; performing a first ion implantation of a second conductivity type into both etched and unetched junction termination areas to form a first ion implantation region; performing a second ion implantation of the second conductivity type, after the first ion implantation, into a portion of both the etched and unetched junction termination areas to form a second ion implantation region; and forming a field oxide layer on a portion of the etched junction termination area through a thermal oxidation process.

Ions implanted during the formation of the field oxide layer may be diffused to form a doping region of a second conductivity type.

A mask pattern used during the formation of the first ion implantation region may be formed such that spacings between the mask patterns gradually decreases toward a chip edge.

Concentrations of ions of the second conductivity type formed during the first ion implantation and the second ion implantation are the same.

The method may further include forming a junction termination etching region after the formation of the field oxide layer; forming a field plate insulating layer in the junction termination etching region; forming a field plate on the field plate insulating layer; forming an interlayer insulating layer on the field plate; and etching a portion of the interlayer insulating layer to form a gate electrode in contact with the field plate and a source electrode in contact with the doping region.

The method may further include performing a grinding process on a bottom surface of the semiconductor substrate; performing an ion implantation process of a second conductivity type, after the grinding process, to form a layer of the second conductivity type; and forming a drain electrode on a bottom surface of the layer.

Other features and aspects will be apparent from the following detailed description, the drawings, and the claims.

### BRIEF DESCRIPTION OF DRAWINGS

FIG. 1 is a cross-sectional view for explaining a semiconductor device according to the related art.

FIG. 2A is a doping concentration profile of the semiconductor device shown in FIG. 1, and FIG. 2B is an electric field profile of the semiconductor device shown in FIG. 1.

FIG. 3 is a cross-sectional view for explaining another semiconductor device having a P-type Bridge Ring (PBR) structure according to the related art.

FIG. 4A is a doping concentration profile of the semiconductor device shown in FIG. 3, and FIG. 4B is an electric field profile of the semiconductor device shown in FIG. 3.

FIGS. 5 to 10 are process diagrams illustrating a method for manufacturing a semiconductor device according to an example of the present disclosure.

FIG. 11 is a cross-sectional view of a semiconductor device manufactured according to the fabrication process of the present disclosure.

FIGS. 12A to 14 are diagrams respectively comparing the impact ionization profile, electric field, and potential of a semiconductor device according to the present disclosure with those of a conventional device.

FIG. 15 is a process flow diagram illustrating a method for manufacturing a semiconductor device according to an example of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with reference to attached drawings.

As is well known, an IGBT semiconductor device includes an active area responsible for conducting current and determining the Rds(on), and a junction termination area supporting the breakdown voltage against the reverse voltage generated during turn-off operation.

The present disclosure provides a semiconductor device and a method of manufacturing the same, which enable stable breakdown voltage performance by providing a lower electric field peak value and a higher breakdown voltage compared to conventional devices.

The present disclosure also provides a semiconductor device and a method of manufacturing the same, which allow for accurate focusing during a photolithography process for the active area of the semiconductor device.

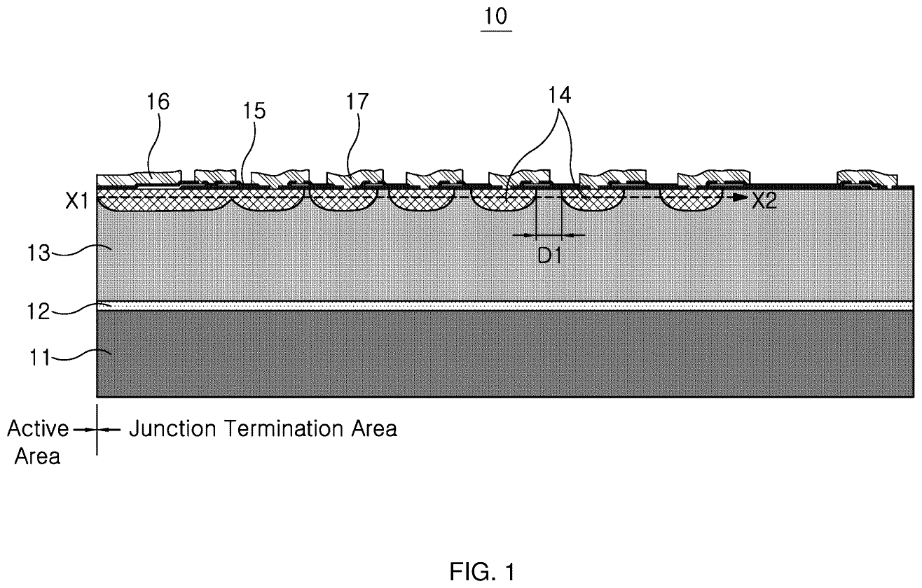

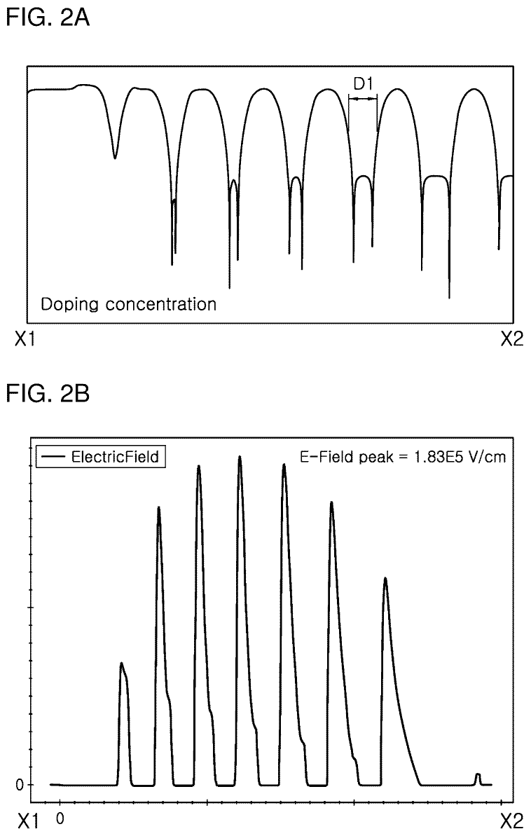

FIG. 1 is a cross-sectional view for explaining a semiconductor device according to the related art. FIG. 2A is a doping concentration profile of the semiconductor device shown in FIG. 1. FIG. 2B is an electric field profile of the semiconductor device shown in FIG. 1.

Referring to FIG. 1, a semiconductor device 10 according to the related art employs a structure in which a floating field ring (FFR) 14 is formed in a junction termination area in order to secure a stable breakdown voltage (BVCES) value. When the floating field ring 14 is formed on the surface of the substrate as shown in FIG. 1, the electric field generated during reverse operation under breakdown conditions can be dispersed from the active area of the semiconductor device 10 toward the chip edge, thereby securing a stable breakdown voltage value.

In the semiconductor device 10, a collector layer 11 is disposed, and a first epitaxial layer 12 is formed on the collector layer 11. A second epitaxial layer 13 is formed on the first epitaxial layer 12, and the second epitaxial layer 13 may be referred to as a drift layer.

The first and second epitaxial layers have a first conductivity type, which may be, for example, an N-type dopant.

The collector layer 11 may have a second conductivity type, such as a P-type dopant.

A collector electrode may be formed beneath the collector layer 11.

A plurality of floating field rings 14 are formed within the second epitaxial layer 13.

A field oxide 15 is formed on the plurality of floating field rings 14.

A plurality of floating electrodes 16, 17 are formed on the field oxide 15.

However, although the structure of the floating field ring 14 is effective for dispersing the electric field, as shown in FIG. 1, the floating field rings 14 are formed with a predetermined spacing D1 therebetween. As a result, in the regions between the floating field rings 14, the electric field may not be adequately supported. The spacing D1 tends to increase toward the chip edge, and the size of the floating field rings 14 tends to decrease accordingly. Therefore, referring to the doping concentration profile X1 to X2 shown in FIG. 2A, the regions between the floating field rings 14 exhibit relatively higher electric field peaks, resulting in problems. Moreover, due to the spacing D1 between the floating field rings 14, a relatively large substrate area may be desired. As shown in FIG. 2B, the inability to adequately support the electric field causes repeated increases and decreases in the electric field peak values, making it difficult to efficiently mitigate the electric field across the middle region.

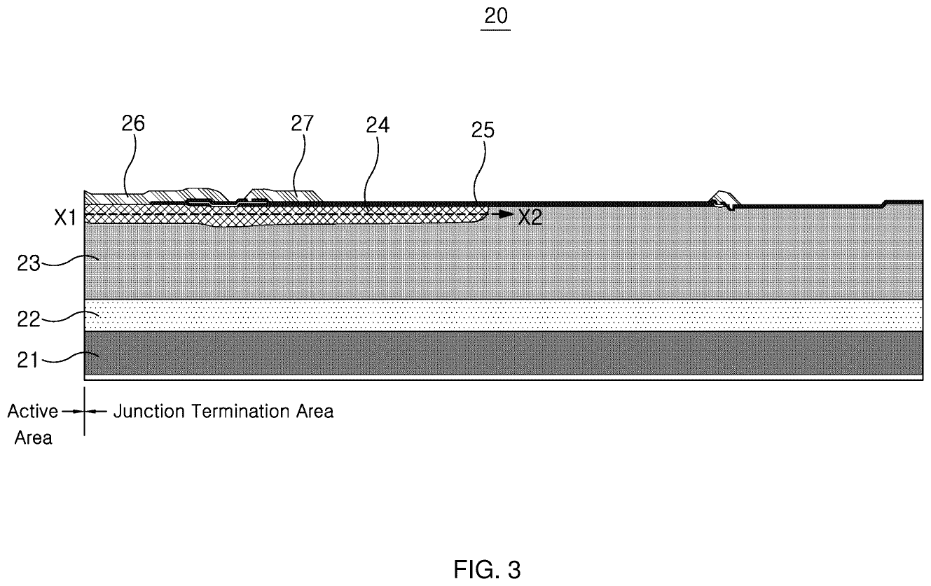

To address these shortcomings, a second conductive or P-type extension region has been proposed in the art, as shown in FIG. 3.

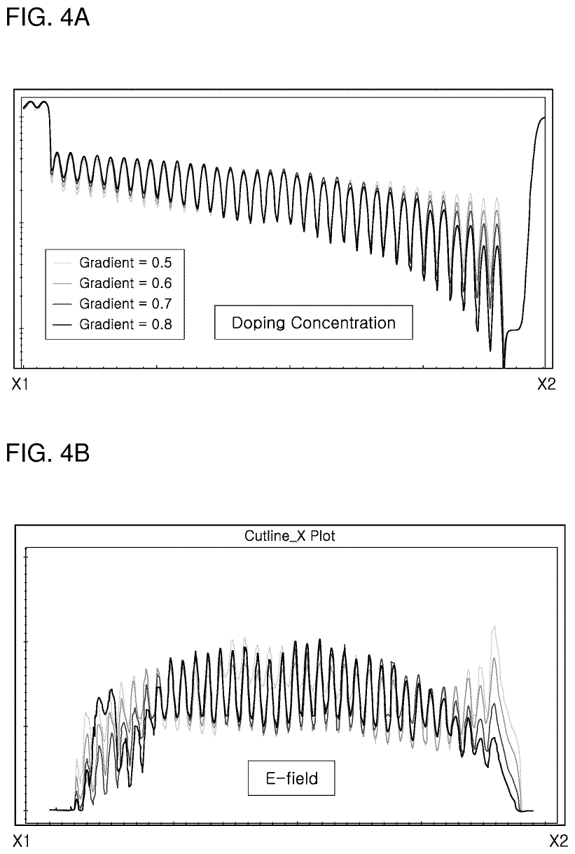

FIG. 3 is a cross-sectional view for explaining another semiconductor device having a PBR structure according to the related art. FIG. 4A is a doping concentration profile of the semiconductor device shown in FIG. 3, and FIG. 4B is an electric field profile of the semiconductor device shown in FIG. 3.

Referring to FIG. 3, a semiconductor device 20 having a PBR structure includes a collector layer 21, a first epitaxial layer 22 formed on the collector layer 21, and a second epitaxial layer 23 formed on the first epitaxial layer 22. The second epitaxial layer 23 may also be referred to as a drift layer.

An extension region 24 having a second conductivity type is disposed within the second epitaxial layer 23, and a field oxide layer 25 is formed over the second conductivity-type extension region 24.

Field plate metals 26, 27 are disposed between the field oxide layers 25.

In FIG. 3, when the second conductivity-type extension region (or P-type extension region) 24 exists in a floating state in the junction termination area, the structure refers to a configuration in which the floating pillar regions are interconnected so as not to remain electrically floating. Compared to FIG. 1, it can be seen that the pillar regions are connected to each other.

The P-type extension region 24 may alternatively be referred to as a variation of lateral doping (VLD) region or a junction termination extension (JTE) area.

Accordingly, the doping concentration of the semiconductor device 20 having the second conductivity-type extension region 24 corresponds to the doping concentration line of the second conductivity-type extension region from X1 to X2 in FIG. 3. As shown in FIG. 4A, the doping concentration in the junction termination area decreases substantially linearly toward the edge. As shown in FIG. 4B, the electric field peak value can also be reduced compared to the conventional structures. Although FIGS. 4A and 4B indicate doping gradients of 0.5, 0.6, 0.7, and 0.8, a greater doping gradient may result in increased ion implantation spacing when forming the PBR structure. Overall, compared to the structure of FIG. 1, the PBR structure facilitates electric field distribution and reduction of electric field peaks, thereby enabling a more stable withstand voltage.

Nevertheless, the semiconductor device 20 having the second conductivity-type extension structure shown in FIG. 3 has drawbacks in that it is difficult to adjust the location of the electric field peak and to control the step between the active area and the junction termination area.

The present disclosure has been devised to address the above-described problems, in which the semiconductor devices of FIGS. 1 and 3 are unable to secure sufficient withstand voltage due to low breakdown voltage and high electric field peaks, and to facilitate the adjustment of the location of the electric field peak. To this end, the present disclosure improves the manufacturing method for the semiconductor device, particularly the process associated with the junction termination area. Accordingly, the following diagrams primarily illustrate the junction termination area, and the manufacturing method of the semiconductor device according to the present disclosure will be described below with reference to the accompanying drawings.

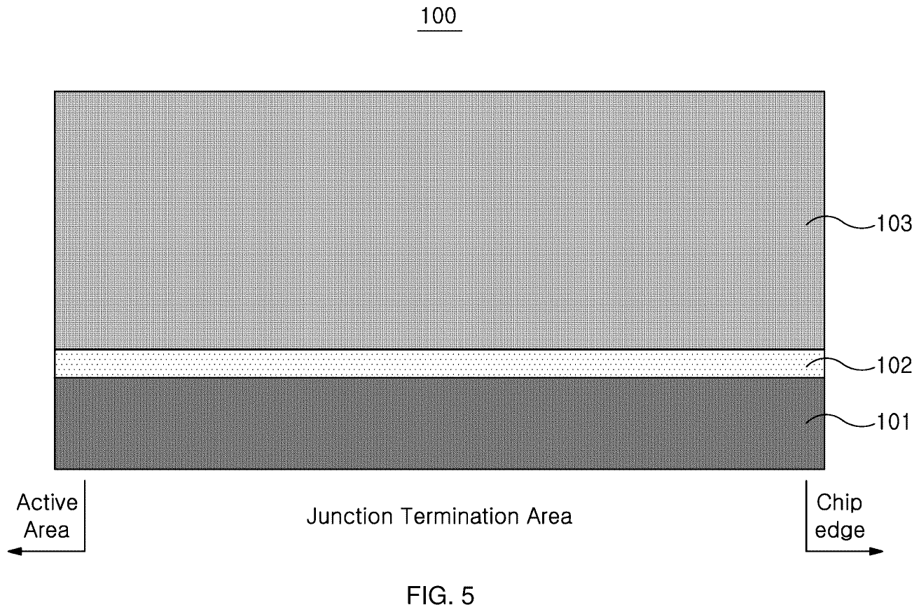

FIGS. 5 to 10 are process diagrams illustrating a method for manufacturing a semiconductor device according to the present disclosure.

Referring to FIG. 5, in order to manufacture a semiconductor device 100, a first epitaxial layer 102 is formed on a semiconductor substrate 101, and a second epitaxial layer 103 (also referred to as a drift layer 103) is formed on the first epitaxial layer 102 using the same dopant. In this example, the semiconductor substrate 101, the first epitaxial layer 102, and the second epitaxial (drift) layer 103 have a first conductivity type, which may be, for example, an N-type dopant.

The semiconductor substrate 101 may be a silicon substrate.

In FIG. 5, the central portion of the semiconductor substrate 101 corresponds to the junction termination area, the left side of the junction termination area represents the active area, and the right side represents the chip edge of the device.

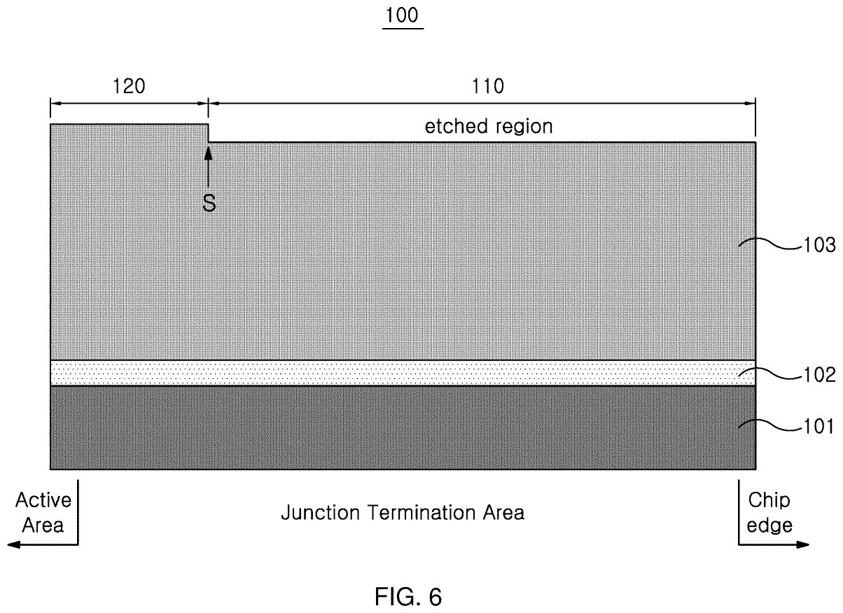

Referring to FIG. 6, a portion of the top surface of the junction termination area is etched. In the drawing, this portion is labeled as the “etched region.” The etched depth corresponds to the thickness of a field oxide layer to be formed in a subsequent process, in order to eliminate a step between the junction termination area and the active area, even after the field oxide layer is later formed.

In the related art, the termination area of a semiconductor device was not etched, and a field oxide layer of a predetermined thickness was directly formed over it. As a result, a step was inevitably formed at the boundary between the junction termination area and the active area due to the field oxide layer. This step caused difficulties in focusing operations using photolithography equipment, particularly during a trench etching process for forming a gate in the active area or during patterning to form a contact region. In the example of the present disclosure, the etching of the junction termination area is intended to eliminate the step between the junction termination area and the active area, thereby allowing accurate focusing on the intended region during a photolithography process.

As shown in FIG. 6, the etching start point S in the junction termination area may be located closer to the active area than to the chip edge. This is related to the location of an emitter region to be formed in a subsequent process. Through this etching process, the junction termination area may be divided into two subregions: a first termination area 110 and a second termination area 120. Based on the etching start point S, the first termination area 110 is located closer to the chip edge, and the second termination area 120 is located closer to the active area. The first termination area 110 refers to the etched region, while the second termination area 120 refers to the non-etched region.

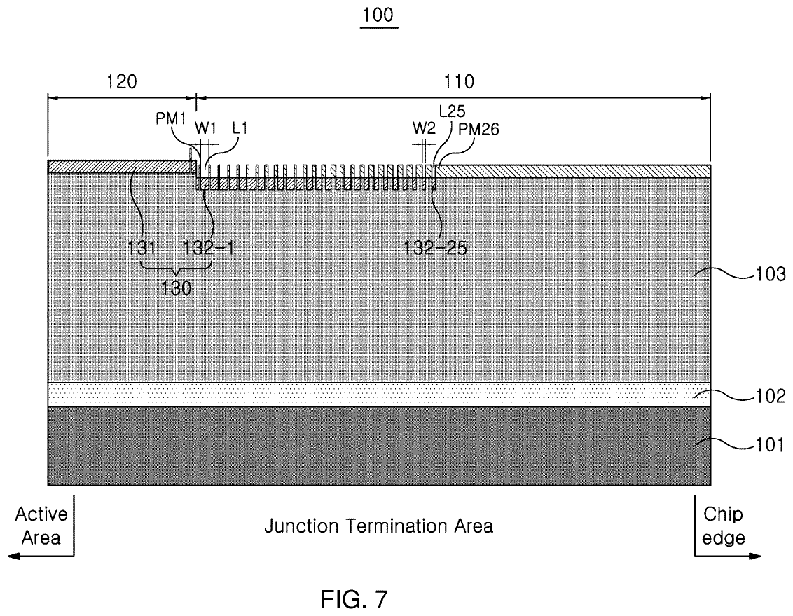

FIG. 7 is a diagram illustrating an ion implantation process for forming a first ion implantation region of a second conductivity type.

As shown in FIG. 7, PBR masks (PM1 to PM26) may be arranged within the first termination area 110 and the second termination area 120. A plurality of openings (L1 to L25) may be patterned in the PBR masks (PM1 to PM26) so that ions of the second conductivity type can be implanted into the upper surface of a second epitaxial layer 103 to form a doped region or PBR region.

Ions of the second conductivity type may be implanted onto the openings of the PBR masks (PM1 to PM26) to form a first ion implantation layer 131, 132-1 to 132-2.

The first ion implantation layer (131, 132-1 to 132-25) may be divided into a first primary ion implantation layer 131 (also referred to as the “1-1 ion implantation layer”), which may be formed as a single ion-implanted region, and a plurality of first secondary ion implantation layers 132-1 to 132-25 (also referred to as the “1-2 ion implantation layers”), which may be formed as multiple discrete ion-implanted regions.

The first primary ion implantation layer 131 and the first secondary ion implantation layers 132-1 to 132-25 may be implanted using boron (B) or another second conductivity-type dopant, and may be formed as P-type regions.

The first primary ion implantation layer and the first secondary ion implantation layers may collectively be referred to as the first ion implantation region 130, also called the PBR ion implantation region.

Specifically, the first secondary ion implantation layers 132-1 to 132-25 are formed such that the width of each unit doping region becomes narrower toward the chip edge of the device. The unit doping regions are spaced apart at predetermined intervals, and conversely, the non-doped regions between the unit doping regions become wider toward the chip edge.

Depending on the width of each opening (L1 to L25) in the PBR masks (PM1 to PM26), the widths of the respective first secondary ion implantation layers 132-1 to 132-25 may vary. The widths of the first secondary ion implantation layers may gradually increase from the chip edge toward the active area.

For example, opening width W1 may be formed wider than opening width W2.

If the concentration of the second conductivity-type dopant is high in the area adjacent to the PBR masks (PM1 to PM26) near the chip edge, the electric field may become concentrated in that region, thereby reducing the reliability of the device.

Accordingly, the width of the PBR ion implantation layer adjacent to the PBR mask may be formed narrower than that of other PBR ion implantation layers so that the implanted dopant concentration is relatively reduced, thereby allowing the electric field near the chip edge to be distributed more broadly. In contrast, in the second PBR region 132, the width of each unit doping region is reduced toward the chip edge. The unit doping regions are formed with a predetermined spacing, and conversely, the non-doped regions between the unit doping regions become wider toward the chip edge.

That is, the mask pattern is characterized in that the spacing between adjacent mask openings becomes narrower toward the chip edge.

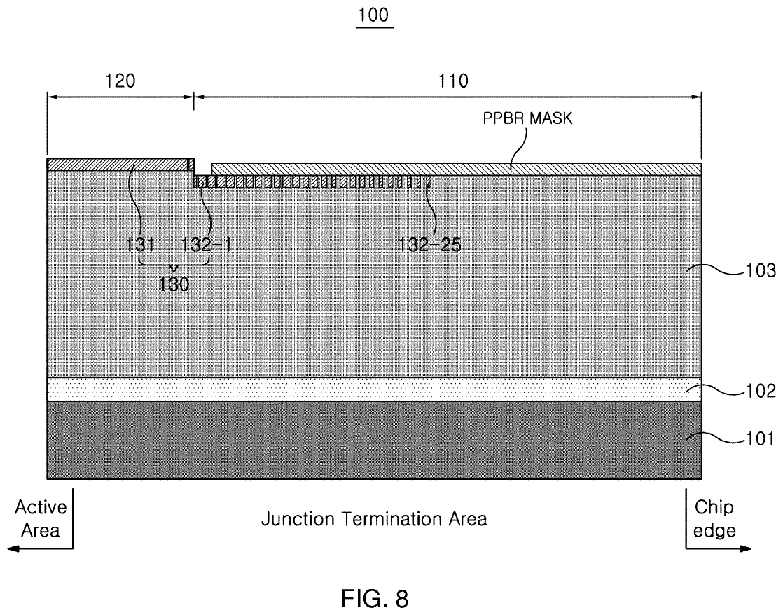

FIG. 8 is a diagram illustrating the formation of a mask for forming a second ion implantation region.

As shown in FIG. 8, a PPBR mask is formed within the first termination area 110. A mask is deposited and patterned over a portion of the first termination area 110 (near the etching point of the first termination area) and over the second termination area 120 in preparation for an additional ion implantation process, thereby forming the PPBR mask in the first termination area 110.

A mask may also be deposited over the active area.

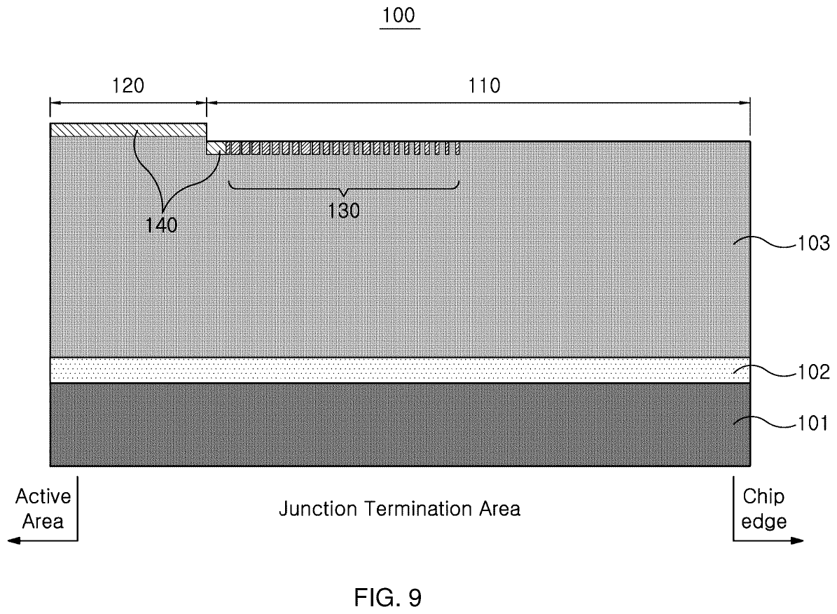

FIG. 9 is a diagram illustrating an ion implantation process for forming a second ion implantation region.

As shown in FIG. 9, a dopant such as boron (B) is additionally implanted into a portion of the first termination area 110 and into the second termination area 120 to form a second ion implantation region 140, which may also be referred to as the PPBR implantation region. The second ion implantation region 140 includes the etching start point S.

The dopant concentration during the second ion implantation may be the same as that of the previously performed first ion implantation; however, due to the additional ion implantation, the overall concentration in the second ion implantation region may become higher than that in the first ion implantation region.

In other examples, the dopant concentration may be adjusted according to the desired breakdown voltage of the semiconductor device.

By implanting ions into the junction termination area in this manner to form the first ion implantation region 130 and the second ion implantation region 140, it is possible to adjust the position of the electric field peak. In other words, the region into which ions are implanted in the semiconductor device may vary depending on the position of the electric field peak.

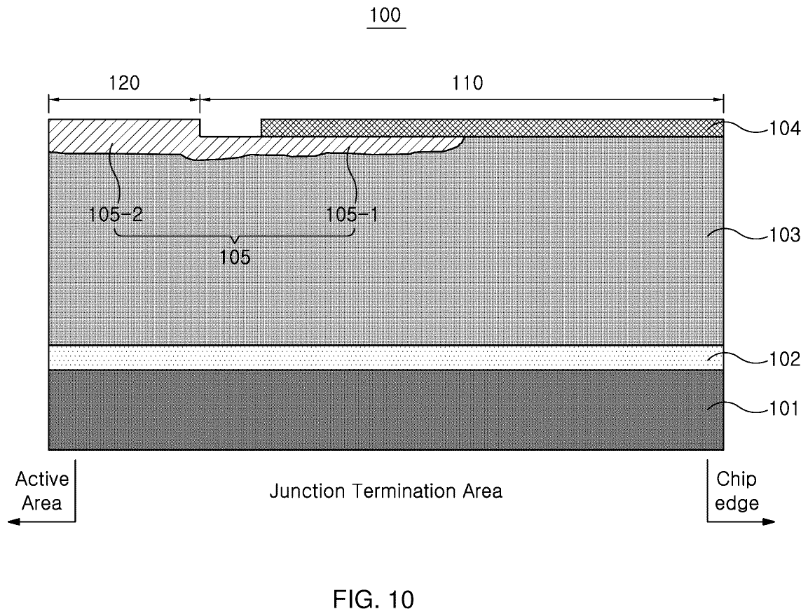

FIG. 10 is a diagram illustrating a process for forming a field oxide layer and a P-type doped region.

Referring to FIG. 10, a field oxide layer 104 is formed on the etched surface of the substrate in the second termination area 120. The field oxide layer 104 is also formed in the first termination area 110, and its thickness corresponds to the previously etched depth. Accordingly, the step between the junction termination area and the active area can be eliminated.

The field oxide layer 104 functions as an insulating and passivation layer capable of withstanding high voltage. The field oxide layer 104 is typically formed of silicon dioxide (SiO₂), which may be deposited on the substrate surface using various deposition methods. Common deposition methods for silicon dioxide include thermal oxidation and chemical vapor deposition (CVD). In this example, for example, a thermal oxidation process may be used, as one example, in which the field oxide layer is formed through a deposition process conducted in a high-temperature furnace at approximately 1000° C. to 1200° C.

When the field oxide layer 104 is formed on the substrate surface using the thermal oxidation process as described above, a high-temperature process is applied. According to this example, the heat generated during the formation of the field oxide layer 104 may also cause thermal diffusion of a second conductivity type doped region 105 into the drift layer 103. The second conductivity type is P-type. That is, the P-type doped region 105 is formed utilizing the heat provided during the formation of the field oxide layer 104.

As described above, in this example, the junction termination area is first etched to a predetermined depth, and a field oxide layer 104 is formed on the etched portion. The heat applied during the formation of the field oxide layer 104 is also used to form the P-type doped region 105 in the substrate. This allows the step between the junction termination area and the active area—caused by the field oxide layer in the related art—to be eliminated.

The second conductivity type doped region 105 may exhibit a difference in concentration due to the previously performed first and second ion implantation processes. A heavily doped region of second conductivity type 105-2 located closer to the active area may undergo both ion implantation processes, resulting in a relatively higher concentration, whereas a lightly doped region 105-1, which undergoes only the first ion implantation process, may have a relatively lower concentration.

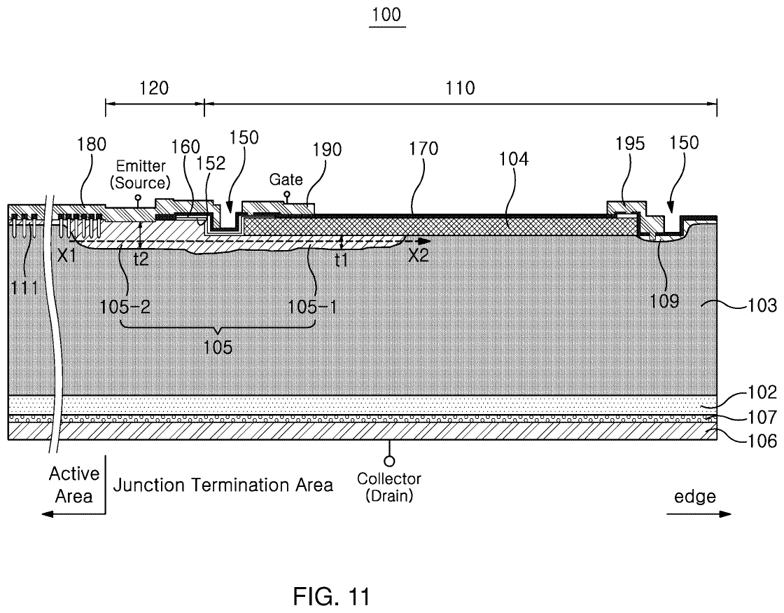

FIG. 11 is a cross-sectional view of a semiconductor device manufactured according to the fabrication process of the present disclosure.

Referring to FIG. 11, a semiconductor device 100 includes a semiconductor substrate 101 that is partially ground to reduce its thickness, allowing for the formation of a second conductivity type collector region in a first direction (i.e., the vertical direction). A P-type dopant is implanted to form a second conductivity type collector region 107. The device further includes a first epitaxial layer 102 and a drift layer 103 formed over the second conductivity type collector region 107. A collector electrode 106 is formed on the backside of the second conductivity type collector region 107.

In the case of a MOSFET, the collector electrode 106 may function as a drain electrode.

As shown in FIG. 11, the semiconductor device 100 may be divided in a second direction (i.e., the horizontal direction), perpendicular to the first direction, into an active area and a junction termination area.

The junction termination area includes a first junction termination area 110 that has been etched and a second junction termination area 120 that remains unetched. The active area and the junction termination area together include the collector electrode 106, the second conductivity type collector region 107, the first epitaxial layer 102, and the second epitaxial (drift) layer 103.

The first junction termination area 110 includes a field oxide layer 104 formed in a region etched to a predetermined depth in the upper surface of the second epitaxial layer 103. The etching depth may be equal to the thickness of the field oxide layer 104, such that no step is created between the junction termination area and the active area. This enables a reliable execution of processes such as trench formation and photolithography in the active area. Within the first junction termination area 110, a portion of the field oxide layer 104 is further etched to form a junction termination etching region 150.

Etching may be performed on both sides of the field oxide layer for process margin, and the etched region may be referred to as the junction termination etching region 150.

A field plate insulating layer (152) is formed on and around the inner and outer upper surfaces of the junction termination etching region 150. A field plate 160 is formed over the field plate insulating layer to a predetermined thickness, and an interlayer insulating layer 170 is formed over the field plate 160 and the field oxide layer 104.

The field plate 160 is formed in a trench shape within the junction termination etching region and may be electrically connected to the second conductivity type doped region 105 through the field plate insulating layer. This structure helps to alleviate the electric field generated during reverse bias conditions.

An emitter electrode 180 and a gate electrode 190 are formed over the interlayer insulating layer 170. The emitter electrode 180 is formed larger than the gate electrode 190, and the emitter contact connected to the emitter electrode is also formed wider, thereby ensuring a sufficient current path during application of a reverse voltage or during breakdown.

In a MOSFET implementation, the emitter electrode 180 may serve as a source electrode.

The gate electrode 190 may be electrically connected or coupled to the field plate 160.

A second conductivity type doped region 105 is formed in the second epitaxial layer 103 of the first conductivity type. The second conductivity type doped region 105 may extend from beneath the field oxide layer 104 to the active area. The second conductivity type doped region 105 is formed by thermal diffusion during the high-temperature process used to form the field oxide layer 104, and overlaps with the first and second ion implantation regions formed in earlier steps.

The second conductivity type doped region 105 may be referred to as a lightly doped region 105-1 or a heavily doped region 105-2, depending on the dopant concentration.

The thicknesses of the lightly doped region 105-1 and the heavily doped region 105-2, which are disposed within the second conductivity type doped region 105, may vary depending on the dopant concentration. The thickness t1 of the lightly region 105-1 is less than the thickness t2 of the heavily region 105-2. The reference surface for measuring the thickness t1 is the etched surface of the second epitaxial layer within the first junction termination area 110, while the reference surface for measuring the thickness t2 is the unetched surface of the second epitaxial layer within the second junction termination area 120.

The dopant concentration of the second conductivity type low-concentration doped region 105-1 may gradually decrease in the X2 direction.

A P-type body region 111, or base region, is formed in the active area and may be connected to the second conductivity type doped region 105.

A trench gate region is formed between second conductivity type body regions 111. A source region or emitter region is formed within each second conductivity type body region 111, and a body contact region of the second conductivity type is formed between adjacent source regions. A source electrode may be electrically connected to both the source regions and the second conductivity type body contact region.

A channel stop region 109 may be formed near the edge of the junction termination area, and a channel stop electrode 195 or an equipotential metal may be formed over the channel stop region. The channel stop region is provided to prevent expansion of the depletion layer into the channel stop region when a high reverse voltage is applied.

The channel stop region may be formed of a first conductivity type or as an N-type region.

As shown in FIG. 11, the field oxide layer 104 is formed in the etched region of the junction termination area, such that the heights of the active area and the junction termination area become aligned due to the field oxide layer 104.

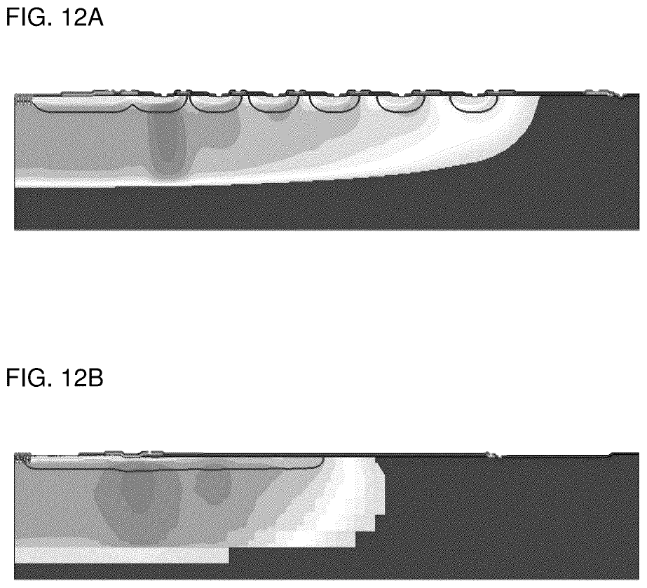

FIG. 12A is a simulation diagram illustrating electric field expansion in a conventional structure, and FIG. 12B is a simulation diagram illustrating electric field expansion in the structure of the present disclosure.

Referring to FIG. 12A, the electric field expands laterally, requiring a certain minimum lateral area to be secured, which may lead to an increase in device size. In addition, due to the presence of N-type regions positioned between the floating field rings, the electric field peak may become elevated, making it difficult to withstand the electric field.

Referring to FIG. 12B, in the structure of the present disclosure, the formation of a second conductivity type doped region reduces lateral expansion of the electric field, thereby enabling a reduction in device size. Furthermore, the concentration of the electric field is mitigated, making it possible to secure a higher breakdown voltage (BVCES) compared to the conventional structure.

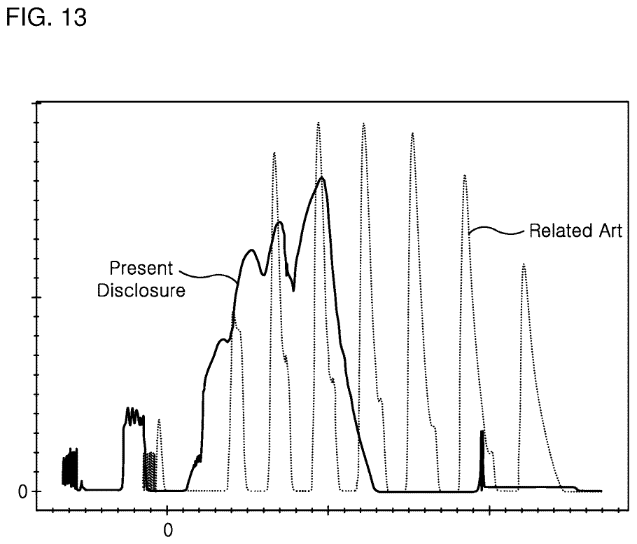

Referring to FIG. 13, electric field graphs of the present disclosure and the related art are illustrated.

In the electric field graph of the related art, an electric field peak phenomenon appears, requiring a sufficient lateral area to withstand the electric field. However, due to the elevated electric field peak, it is difficult to ensure device reliability and secure a stable breakdown voltage.

In contrast, the electric field graph of the present disclosure shows a streamlined or parabolic electric field profile in which the electric field peak is stably controlled. As a result, improved device reliability and a stable breakdown voltage can be achieved.

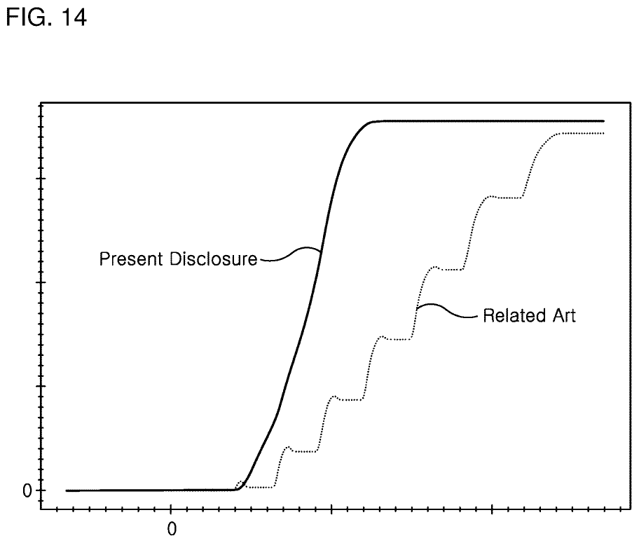

FIG. 14 is an electric field potential graph obtained by integrating the electric field graph of FIG. 13.

As shown in FIG. 13, the electric field potential curve of the present disclosure increases linearly, enabling stable reverse operation. In contrast, the electric field potential curve of the related art rises in an unstable, step-like manner.

The differences in P-type ring length (junction termination area), electric field peak, and breakdown voltage (BVCES) between the conventional structure and the structure of the present disclosure are summarized in Table 1 below.

TABLE 1

| | | | Structure of the Present | |
|---|---|---|---|---|
| Item | Conventional Structure | | Disclosure | |
| P-type Ring Length | Mid-200 | μm | Mid-100 | μm |
| Electric Field Peak | 1.85E+5 | V/cm | 1.61E+5 | V/cm |
| BVCES | 688 | V | 711 | V |

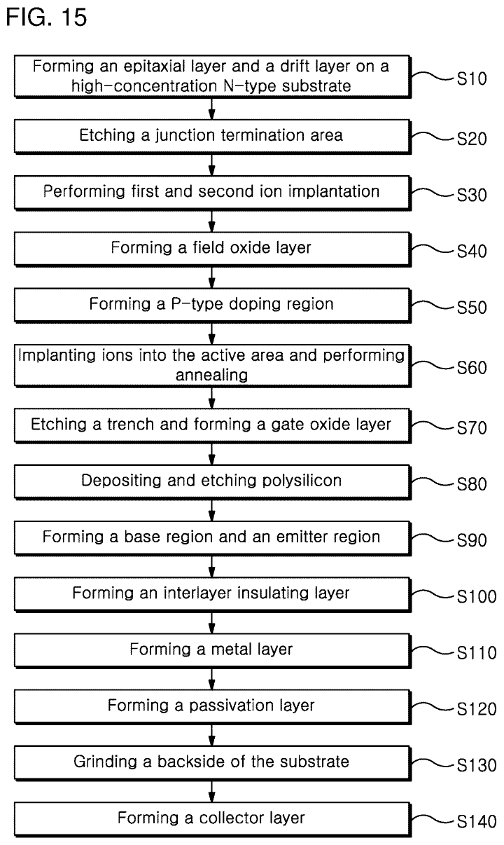

FIG. 15 is a process flow diagram illustrating a method for manufacturing a semiconductor device according to an example of the present disclosure.

Referring to FIG. 15, a method for manufacturing a semiconductor device according to one example of the present disclosure includes the following processes: forming an epitaxial layer on a semiconductor substrate (S10); etching a junction termination area of the semiconductor substrate (S20); performing first and second ion implantations into the junction termination area (S30); forming a field oxide layer in the junction termination area (S40); forming a P-type doped region in the substrate during formation of the field oxide layer (S50); implanting N-type ions into the active area in the semiconductor substrate and performing a thermal annealing process (S60); etching a trench in the junction termination area and forming a gate oxide layer in the junction termination area; depositing and etching polysilicon on the gate oxide layer (S80); forming a base region and an emitter region in the semiconductor substrate (S90); forming an interlayer insulating layer (S100); forming a metal layer over the interlayer insulating layer (S110); forming a passivation layer over the metal layer (S120); grinding and polishing a backside of the semiconductor substrate and forming a collector region (S130); and forming a collector layer on the backside of the semiconductor substrate (S140).

The processes corresponding to the improvements of the present disclosure include processes S20 to S50. Processes from S60 onward generally follow known semiconductor fabrication processes.

A brief explanation of the fabrication process in FIG. 15 is as follows.

An epitaxial layer 102 and a drift layer 103 are formed on a semiconductor substrate 101. The semiconductor substrate 101 includes an active area and a junction termination area, and in the present disclosure, the portion of the epitaxial layer that is etched may correspond to the junction termination area.

The junction termination area is etched to a predetermined depth. Based on an etching start point (S in FIG. 6), the unetched portion may be referred to as a first termination area 110, and the etched portion may be referred to as a second termination area 120.

A first ion implantation is performed into both the first termination area 110 and the second termination area 120, followed by a second ion implantation into part of the first ion-implanted region.

A field oxide layer 104 is then formed in the second termination area, and a P-type dopant is introduced into the substrate by heat generated during the formation of the field oxide layer 104, thereby forming a P-type doping region 105. The P-type doping region 105 is formed to be electrically connected from beneath the field oxide layer 104 to the active area.

An N-type ion implantation and annealing process are performed in the active area.

A trench 130 is then etched in the active area, and a gate oxide layer is formed within the trench.

Polysilicon 160 is deposited on the gate oxide layer, and the polysilicon is etched to form a gate region.

A P-type dopant is implanted to form a base region, and a thermal process is performed at a predetermined temperature. Subsequently, P⁺ and N⁺ dopants are implanted to form an emitter region and a base contact region.

After the emitter region is formed, an interlayer insulating layer 170 is deposited and a contact photoresist layer is formed. Then, to form an emitter contact, the interlayer insulating layer 170 is etched, the photoresist layer is removed, and metal wiring is formed for the emitter metal, a gate via, and a gate bonding pad.

A passivation layer (e.g., an oxide film and a nitride film) is formed.

When the processing of the front side of the semiconductor substrate is completed through the above-described steps, processing on the backside of the semiconductor substrate may be performed.

The backside processing includes grinding and cleaning the backside of the semiconductor substrate, performing a P-type ion implantation process on the backside to form a collector layer of a second conductivity type, and depositing a metal layer thereon to form a collector electrode.

As described above, the present disclosure provides a method of manufacturing a semiconductor device in which the semiconductor substrate is etched by a depth corresponding to the thickness of a field oxide layer to be subsequently formed, prior to forming the field oxide layer in the junction termination area. By forming the field oxide layer after such etching, a step difference between the active area and the junction termination area is eliminated. It can be seen that the semiconductor device manufactured through this process provides a lower electric field value and a higher breakdown voltage compared to conventional devices.

According to the present disclosure, a semiconductor device having stable breakdown characteristics can be provided, as it offers a lower electric field peak value and a higher breakdown voltage or device withstand voltage compared to conventional semiconductor devices.

In addition, since the present disclosure allows the removal of a step difference between the active area and the junction termination area during the manufacturing process, it enables accurate focusing in a photolithography process for the active area in subsequent processing steps.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
an active area and a junction termination area, each comprising;
a drain electrode;
a first epitaxial layer of a first conductivity type disposed on the drain electrode; and
a second epitaxial layer of the first conductivity type disposed on the first epitaxial layer,
wherein the junction termination area further comprises a first junction termination area etched on a portion of the second epitaxial layer, and a second junction termination area that is not etched,
wherein a field oxide layer is disposed on a portion of the first junction termination area, and
wherein a doped region of a second conductivity type is disposed to extend from beneath the field oxide layer to the second junction termination area.

2. The semiconductor device of claim 1,
wherein the doped region comprises:
a lightly doped region of the second conductivity type disposed in the first junction termination area; and
a heavily doped region of the second conductivity type disposed to extend from the first junction termination area to the second junction termination area.

3. The semiconductor device of claim 2,
wherein a thickness of the heavily doped region is greater than a thickness of the lightly doped region.

4. The semiconductor device of claim 1,
wherein a surface of the field oxide layer is coplanar with a surface of the second epitaxial layer present in the second junction termination area.

5. The semiconductor device of claim 1, further comprising:
a body region of the second conductivity type disposed between trench gates in the active area,
wherein the body region is connected to the doped region.

6. The semiconductor device of claim 1, further comprising:
a layer of a second conductivity type formed between the drain electrode and the first epitaxial layer.

7. The semiconductor device of claim 1,
wherein the junction termination area further comprises:
a junction termination etching region disposed between the field oxide layer and the second junction termination area;
a field plate insulating layer disposed on inner and outer upper surfaces of the junction termination etching region;
a field plate disposed on the field plate insulating layer;
an interlayer insulating layer disposed on the field plate; and
a source electrode and a gate electrode formed on the interlayer insulating layer.

8. A semiconductor device comprising:
an active area and a junction termination area, each comprising:
a drain electrode;
a first epitaxial layer of a first conductivity type disposed on the drain electrode; and
a second epitaxial layer of the first conductivity type disposed on the first epitaxial layer,
wherein the junction termination area further comprises a first junction termination area etched on a portion of the second epitaxial layer, and a second junction termination area that is not etched,
wherein a field oxide layer is disposed on a portion of the first junction termination area; and
wherein doping regions of a second conductivity type with different thicknesses are disposed in the first junction termination area and the second junction termination area.

9. The semiconductor device of claim 8, further comprising:
a body region of the second conductivity type formed between trench gates in the active area,
wherein the body region is connected to the doped region.

10. The semiconductor device of claim 8,
wherein the doped regions comprise:
a lightly doped region of the second conductivity type disposed on the first junction termination area, and
a heavily doped region of the second conductivity type disposed to extend from the first junction termination area to the second junction termination area and having a higher doping concentration than the lightly doped region of the second conductivity type.

11. The semiconductor device of claim 10,
wherein a thickness of the heavily doped region is greater than a thickness of the lightly doped region.

12. The semiconductor device of claim 10,
wherein a doping concentration of the lightly doped region gradually decreases toward an edge of the first junction termination area.

13. The semiconductor device of claim 10, further comprising:
a source electrode electrically contacting the heavily doped region;
a field plate disposed on a portion of the heavily doped region and on the lightly doped region; and
a gate electrode electrically contacting the field plate.

14. The semiconductor device of claim 10, further comprising:
a layer of a second conductivity type formed between the drain electrode and the first epitaxial layer.

15. A method of manufacturing a semiconductor device including an active area and a junction termination area, the method comprising:
forming a first epitaxial layer of a first conductivity type on a semiconductor substrate of the first conductivity type;
forming a second epitaxial layer of the first conductivity type on the first epitaxial layer;
etching an upper surface portion of the second epitaxial layer located in the junction termination area;
performing a first ion implantation of a second conductivity type into both etched and unetched junction termination areas to form a first ion implantation region;
performing a second ion implantation of the second conductivity type, after the first ion implantation, into a portion of both the etched and unetched junction termination areas to form a second ion implantation region; and
forming a field oxide layer on a portion of the etched junction termination area through a thermal oxidation process.

16. The method of claim 15,
wherein ions implanted during the formation of the field oxide layer are diffused to form a doping region of a second conductivity type.

17. The method of claim 15,
wherein a mask pattern used during the formation of the first ion implantation region is formed such that spacings between the mask patterns gradually decreases toward a chip edge.

18. The method of claim 15,
wherein concentrations of ions of the second conductivity type formed during the first ion implantation and the second ion implantation are the same.

19. The method of claim 15, further comprising:
forming a junction termination etching region after the formation of the field oxide layer;
forming a field plate insulating layer in the junction termination etching region;
forming a field plate on the field plate insulating layer;
forming an interlayer insulating layer on the field plate; and
etching a portion of the interlayer insulating layer to form a gate electrode in contact with the field plate and a source electrode in contact with the doping region.

20. The method of claim 15, further comprising:
performing a grinding process on a bottom surface of the semiconductor substrate;
performing an ion implantation process of a second conductivity type, after the grinding process, to form a layer of the second conductivity type; and
forming a drain electrode on a bottom surface of the layer.
